(19) United States
(12) Patent Application Publication
(10) Pub. No.: US 2015/0104376 A1
(43) Pub. Date: Apr. 16, 2015

(54) METHOD OF ANNEALING SAPPHIRE

(71) Applicant: GT Crystal Systems, LLC, Salem, MA (US)

(72) Inventors: Scott J. Turchetti, Peterborough, NH (US); Daniela M. Fredrick, San Anselmo, CA (US)

(21) Appl. No.: 14/489,924

(22) Filed: Sep. 18, 2014

Related U.S. Application Data
(60) Provisional application No. 61/891,650, filed on Oct. 16, 2013.

(51) Int. Cl. C01F 7/02; H05K 5/03

(52) U.S. Cl. CPC C01F 7/021; H05K 5/03
USPC 423/625; 65/32.1

(57) ABSTRACT

A method of annealing at least one sapphire lamina is disclosed. The method comprises at least two different heating steps and produces an annealed sapphire lamina having improved optical properties that can be used for fabricating a cover plate of an electronic device. The cover plate and electronic device comprising the annealed sapphire lamina are also disclosed.

### CROSS-REFERENCE TO RELATED APPLICATION

The present application claims the benefit of U.S. Patent Application No. 61/891,650 filed Oct. 16, 2013, which is incorporated herein by reference.

### BACKGROUND OF THE INVENTION

1. Field of the Invention

The present invention relates to a sapphire processing and to electronic device comprising a sapphire cover plates.

2. Description of the Related Art

There are many types of mobile electronic devices currently available which include a display window assembly that is at least partially transparent. These include, for example, handheld electronic devices such media players, mobile telephones (cell phones), personal data assistants (PDAs), pagers, tablets, and laptop computers and notebooks. The display screen assembly may include multiple component layers, such as, for example, a visual display layer such as a liquid crystal display (LCD), a touch sensitive layer for user input, and at least one outer cover layer used to protect the visual display. Each of these layers are typically laminated or bonded together.

Many of the mobile electronic devices used today are subjected to excessive mechanical and/or chemical damage, particularly from careless handling and/or dropping, from contact of the screen with items such as keys in a user's pocket or purse, or from frequent touch screen usage. For example, the touch screen surface and interfaces of smartphones and PDAs can become damaged by abrasions that scratch and pit the physical user interface, and these imperfections can act as stress concentration sites making the screen and/or underlying components more susceptible to fracture in the event of mechanical or other shock. Additionally, oil from the use's skin or other debris can coat the surface and may further facilitate the degradation of the device. Such abrasion and chemical action can cause a reduction in the visual clarity of the underlying electronic display components, thus potentially impeding the use and enjoyment of the device and limiting its lifetime.

Various methods and materials have been used in order to increase the durability of the display windows of mobile electronic devices. For example, polymeric coatings or layers can be applied to the touch screen surface in order to provide a barrier against degradation. However, such layers can interfere with the visual clarity of the underlying electronic display as well as interfere with the touch screen sensitivity. Furthermore, as the coating materials are often also soft, they can themselves become easily damaged, requiring periodic replacement or limiting the lifetime of the device.

Another common approach is to use more highly chemically and scratch resistant materials as the outer surface of the display window. For example, touch sensitive screens of some mobile devices may include a layer of chemically-strengthened alkali aluminosilicate glass, with potassium ions replacing sodium ions for enhanced hardness, such as the material referred to as Gorilla® glass available from Corning. However, even this type of glass can be scratched by many harder materials, including metal keys, sand, and pebbles, and, further, as a glass, is prone to brittle failure and shattering.

Sapphire has also been suggested and used as a material for either the outer layer of the display assembly or as a separate protective sheet to be applied over the display window. However, sapphire is relatively expensive, particularly at the currently available thicknesses, and reducing a layer of sapphire to a more desirable thickness adds considerable cost and time. Furthermore, post-processing of the sapphire layer, such as annealing, is often needed to order to produce material meeting the desired high optical quality required for the electronic device markets, and currently available methods typically produce material with unacceptable haze and other optical defects.

Therefore, while sapphire materials are available which can enable the display of a mobile electronic device to be relatively resistant to damage, there remains a need for methods of producing layers of high optical quality sapphire meeting the highly demanding needs of the electronic device industry.

### SUMMARY OF THE INVENTION

The present invention relates to a method of producing a cover plate of an electronic device. The method comprises the steps of providing at least one sapphire lamina and heating the sapphire lamina at a first temperature and under vacuum at a first pressure. The sapphire layer is also heated at a second temperature and in an inert gaseous atmosphere at a second pressure, preferably following the first heating step. The second temperature is greater than the first temperature and the second pressure is greater than the first pressure. The sapphire lamina is then cooled to room temperature, thereby producing an annealed sapphire lamina. The method further comprises the step of fabricating the cover plate comprising the annealed sapphire lamina. The present invention further relates to the fabricated cover plate produced by the disclosed method as well as an electronic device, particularly a mobile electronic device, comprising the cover plate.

It is to be understood that both the foregoing general description and the following detailed description are exemplary and explanatory only and are intended to provide further explanation of the present invention, as claimed.

### DETAILED DESCRIPTION OF THE INVENTION

The present invention relates to methods of annealing a sapphire lamina and cover plates and electronic devices comprising the annealed sapphire lamina.

In the method of the present invention, at least one sapphire material is provided, preferably in the form of a sheet or layer, such as a sapphire lamina or wafer. In particular, the sapphire material can be a sapphire lamina having at thickness of less than about 5 mm, including less than about 2 mm or less than about 1 mm, such as a sapphire lamina having a thickness of from about 0.1 mm to about 1 mm, including from about 0.2 mm to about 1 mm. More than one sapphire lamina can be provided in the present method, including, for example, from 50 to 2000 lamina, and are preferably processed simultaneously as a single batch.

The sapphire lamina can be any sapphire material known in the art. For example, it is known that sapphire may include one of several different crystalline axes, such as the c-axis, the m-axis, or the a-axis, and the properties of a sapphire lamina vary depending on this crystal orientation. The sapphire lamina used in the method of the present invention can have any known crystalline orientation, as well as off-axis orientations (such as between about 0 and 18 degrees off-axis). Furthermore, the sapphire lamina can be prepared using a variety of different methods. For example, the sapphire lamina can be prepared by cutting or slicing layers from a donor sapphire material and mechanically grinding or chemically etching the resulting material down to the desired thickness. An optional polishing step may be used if needed to remove any unwanted surface defects. Thus, the sapphire lamina can be prepared by a method comprising the steps of providing a layer of sapphire having an initial thickness, reducing the layer of sapphire from the initial thickness to a desired thickness, such as a thickness of from about 0.1 mm to about 1 mm, and optionally polishing the layer of sapphire. Alternatively, very thin sapphire layers, such as those having a thickness of less than about 0.1 mm, can be prepared using various layer transfer methods known to remove thin layers from a sapphire donor material, including, for example, controlled spalling or ion implantation and exfoliation method.

The sapphire from which the sapphire lamina is prepared can be produced using any method known in the art. For example, the sapphire material can be prepared in a crystal growth apparatus, which is a high-temperature furnace capable of heating and melting a solid feedstock, such as alumina, in a crucible at temperatures generally greater than about 1000° C. and subsequently promoting resolidification of the resulting melted feedstock material to form a crystalline material, such as a sapphire boule. Preferably, the sapphire is prepared in a heat exchanger method crystal growth furnace, in which a crucible comprising alumina feedstock and at least one single crystal sapphire seed is heated above its melting point to melt the feedstock without substantial melting of the seed, and heat is then removed from the crucible using a heat exchanger, such as a helium-cooled heat exchanger, provided in thermal communication with the bottom of the crucible and positioned under the seed. This method has been shown to produce large, high quality sapphire boules from which the sapphire can be readily removed using available methods. For example, the sapphire lamina can be sliced or cut from a cylindrical portion of a sapphire boule and, as such, is provided in wafer form, having a thickness of, for example, greater than about 0.1 mm, such as from about to 0.2 mm to about 1 mm. Alternatively, the sapphire can be prepared by other known crystal growth methods and apparatuses, including, for example, using edge-defined film-fed growth (EFG) or Kyropoulos growth methods.

In the method of the present invention, the sapphire lamina is heated at a first temperature and under vacuum at a first pressure. Thus, the sapphire lamina is subjected to a high temperature annealing step under vacuum. The material can be heated in any apparatus known in the art, such as in a high temperature annealing furnace or oven that is configured for heating under both vacuum as well as at high pressures, as discussed below. Furthermore, the sapphire lamina can be provided in a holder or rack that is then placed within the heating apparatus. This is particularly preferred when a plurality of sapphire lamina are heated. The rack or holder can be made of any material capable of withstanding the required temperature and atmospheric conditions.

For this heating step, preferably, for sapphire, the first temperature is from about 900°C. to about 2000°C. (i.e., below the melting point of sapphire), more preferably from about 1400°C. to about 1800°C., and most preferably from about 1500°C. to about 1700°C. The first pressure is significantly below atmospheric pressure, such as below about 1 torr, including from about 10⁻¹ torr to about 10⁻⁷ torr and from about 10⁻² torr to about 10⁻⁶ torr. The sapphire lamina is heated under these conditions for an amount of time that can vary depending on several factors, including the size of the lamina, the lamina thickness, the number of lamina being heated, and the specific temperature/pressure combination used. Typically, the sapphire lamina is heated at the first temperature and low pressure for less than 6 hours, such as from about 0.5 to about 2 hours.

In addition, in the method of the present invention, the sapphire lamina is also heated at a second temperature and in an inert gaseous atmosphere at a second pressure that is higher than the first pressure. Thus, the sapphire lamina is also subjected to a high temperature annealing step in an inert gas. As discussed above, the sapphire material can be heated in any apparatus known in the art, such as in a high temperature annealing furnace or oven that is configured for heating under both vacuum as well as at high pressures. Preferably the apparatus used for this heating step is the same as used for the vacuum heating step.

For this additional heating step, the second temperature is higher than the first temperature. Thus, preferably, the second temperature is from about 1000° C. to about 2050° C. (but still below the melting point of sapphire), more preferably from about 1500°C. to about 2000°C., and most preferably from about 1600° C. to about 1800°C. In addition, the second pressure is significantly higher than the first pressure. Thus, for example, the second pressure can be between the first pressure and atmospheric pressure, although significantly higher pressures can also be used, including as high as 1500 torr or higher, depending on the pressure rating of the furnace or apparatus used, which may be as high as 7500 torr. Preferably, the second pressure is at or about atmospheric pressure, although some over-pressure is possible due to the presence of the gaseous atmosphere. The atmosphere in which the sapphire lamina is heated in this additional heating step is an inert gaseous atmosphere, comprising at least one inert gas, such as helium or argon. Preferably, the inert gaseous atmosphere comprises argon. The gaseous atmosphere may be stationary or flowing, and the flow rate can vary depending on a variety of factors, such as the size and number of lamina as well as the size of the apparatus in which the lamina are heated. Also, the sapphire lamina can be heated under these conditions for an amount of time that can vary as discussed above but is typically less than 6 hours, such as from about 0.5 to about 2 hours.

Thus, the method of the present invention is a multistep annealing method comprising at least two different heating steps—a high temperature heating under vacuum and a high temperature heating in an inert gaseous atmosphere. These steps can occur in either order. In addition, either or both of these steps may be repeated as desired. Preferably, the sapphire lamina is heated under vacuum at the first temperature and is then subsequently heated at a higher temperature in the inert gaseous atmosphere. Also, preferably, a plurality of sapphire lamina is heated simultaneously, and both steps occur in the same high temperature heating apparatus. Thus, as a specific example, a plurality of sapphire lamina was positioned in an annealing oven and heated at a temperature of from about 1500°C. to about 1700°C. under vacuum, at a pressure from about 10⁻² torr to about 10⁻⁶ torr for 0.5 to 2 hours. Argon gas was then delivered into the system, increasing the pressure to approximately atmospheric pressure. In addition, the temperature was increased, and the plurality of sapphire lamina was heated at about 1600° C. to about 1800°C. in the argon atmosphere.

The method of the present invention may further comprise a cooling step between heating steps. Thus, for example, the sapphire lamina may be heated under vacuum at a first temperature, cooled to a temperature below the first temperature, such as room temperature, and subsequently reheated to a second temperature, which is greater than the first temperature, this time in an inert gaseous atmosphere. This optional cooling step has been found to be preferred when the sapphire lamina are contained within a holder or rack, such as a tungsten rack, having a heat capacity greater than sapphire.

Also, the method of the present invention may further comprise the step of heating the sapphire lamina at a third temperature and in a gaseous atmosphere comprising hydrogen at a third pressure. This additional heating step may occur prior to heating the sapphire lamina in the inert gaseous atmosphere and/or prior to heating the lamina under vacuum. Furthermore, this step of heating in a gaseous atmosphere comprising hydrogen may also be used as an alternative to either of the previously described heating steps, depending on the desired properties of the annealed sapphire lamina. In particular, heating in a hydrogen atmosphere may be used in place of heating under vacuum. For this step, the third temperature is below the second temperature and is preferably from about 900°C. to about 2000°C. (i.e., below the melting point of sapphire), more preferably from about 1000° C. to about 1800°C., and most preferably from about 1200° C. to about 1500°C. The third pressure is above the first pressure and is preferably between the first pressure and atmospheric pressure, more preferably at or about atmospheric pressure, although some over-pressure is possible due to the presence of the gaseous atmosphere. The hydrogen atmosphere may comprise wet hydrogen, such as can be produced by bubbling hydrogen gas through water. Alternatively, the hydrogen atmosphere may comprise hydrogen and an inert gas, such as helium or argon.

After the steps of heating at the first and second temperatures, the sapphire lamina can then be cooled to room temperature and removed from the heating apparatus. The resulting annealed sapphire lamina were found to have similar or improved mechanical and physical properties compared to the starting sapphire lamina. For example, at room temperature, the annealed sapphire lamina preferably has a flexural strength of at least about 700 MPa, including between about 800 and 1000 MPa, a fracture toughness (i.e., the ability of the material containing a crack or scratch to resist fracture) of greater than 1 MPa, including between about 2 and 5 MPa, a Knoop hardness of greater than about 15 GPa, including between about 17 and about 20 GPa, and/or a Vickers hardness of greater about 1000 kg/m, including between about 2000 and 3000 kg/m. The modulus, such as the Young's modulus, is also similar or improved compared to the modulus of the starting sapphire lamina, which is typically between about 300-400 GPa, but can vary depending on the desired properties of the cover plate (such as touch sensitivity). Furthermore, the annealed sapphire lamina, prepared using the method of the present invention, were found to have improved optical properties, such as reduced haze, compared to sapphire lamina prepared using other known high temperature annealing methods.

In particular, it was found that sapphire lamina annealed using the method of the present invention have improved failure under load versus comparatively annealed samples. For example, annealed sapphire lamina prepared using the two heating steps described above were found to fail on average (as measured using a ring-on-ring load test) under a load of approximately 7500 Newtons while sapphire lamina annealed by heating under vacuum only or in an argon atmosphere only (under similar temperature conditions) were found to fail on average under a load of approximately 5500 Newtons. In addition, the average haze values for the sapphire lamina prepared using the method of the present invention were also improved versus the comparative samples.

The annealed sapphire lamina prepared by the method of the present invention can be used to fabricate cover plates for a variety of different electronic devices. Thus, the present invention further relates to cover plates comprising sapphire lamina annealed using the methods described above as well as to electronic devices comprising these cover plates. In particular, the cover plate can have at least one transparent display region through which an image can be displayed, such as from a display element of an electronic device upon which the cover plate is placed. Non-transparent regions may also be present, particularly as decorative elements such as borders or as elements to delineate various functional sections of the display. The electronic device can be any known in the art comprising a display or display element, such as mobile or portable electronic devices including, but not limited to, electronic media players for music and/or video, such as an mp3 player, mobile telephones (cell phones), personal data assistants (PDAs), pagers, laptop computers, or electronic notebooks or tablets. The display element of the device may include multiple component layers, including, for example, a visual display layer such as an LCD and a touch sensitive layer as part of a touch screen application. The cover plate can be affixed to the display surface of the display element of the device or it can be a separate protective layer that can be placed or positioned over or on top of the display element and later removed if desired.

The cover plate of the present invention can comprise one or more of the annealed sapphire lamina or may be a single, free-standing sapphire lamina. For sapphire multilayer composites, preferably, the sapphire lamina is the exterior layer of the cover plate and the electronic device. The overall thickness of the cover plate of the present invention can vary depending on a variety of factors, including, for example, the number of layers, the desired size of the transparent display region, and the size of the device. In general, the cover plate has a thickness that is less than about 5 mm, such as less than about 3 mm, for a multilayer cover plate.

The cover plate may comprise a sapphire layer combined with one or more permanent or temporary carrier substrates or layers that provide additional desirable features to the cover plate. For example, the cover plate may further comprise a transparent layer affixed to the sapphire layer. The transparent layer can be any transparent material known in the art including, for example, a layer comprising glass, such as soda-lime, borosilicate, or aluminosilicate glass, including chemically-strengthened alkali aluminosilicate glass (such as the material referred to as Gorilla® glass available from Corning), or a layer comprising a polymeric material, such as a polycarbonate or a polymethacrylate such as polymethyl methacrylate (PMMA). The sapphire layer and the transparent layer may be combined using any technique known in the art, forming an interface in between.

The foregoing description of preferred embodiments of the present invention has been presented for the purposes of illustration and description. It is not intended to be exhaustive or to limit the invention to the precise form disclosed. Modifications and variations are possible in light of the above teachings, or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

What is claimed is:

1. A method of producing a cover plate of an electronic device comprising the steps of:
i) providing at least one sapphire lamina;
ii) heating the sapphire lamina at a first temperature and under vacuum at a first pressure;
iii) heating the sapphire lamina at a second temperature and in an inert gas at a second pressure, wherein the second temperature is greater than the first temperature and the second pressure is greater than the first pressure;
iv) cooling the sapphire lamina to room temperature to produce an annealed sapphire lamina; and
v) fabricating the cover plate comprising the annealed sapphire lamina.

2. The method of claim 1, wherein the sapphire lamina has a thickness of from about 0.1 mm to about 2 mm.

3. The method of claim 2, wherein the thickness of the sapphire lamina is from about 0.2 mm to about 1 mm.

4. The method of claim 1, wherein the first temperature is from about 900°C. to about 2000°C.

5. The method of claim 1, wherein the first temperature is from about 1400° C. to about 1800°C.

6. The method of claim 1, wherein the first temperature is from about 1500° C. to about 1700°C.

7. The method of claim 1, wherein the second temperature is from about 1000° C. to about 2050° C.

8. The method of claim 1, wherein the second temperature is from about 1500° C. to about 2000°C.

9. The method of claim 1, wherein the second temperature is from about 1600° C. to about 1800°C.

10. The method of claim 1, wherein the first pressure is less than about 1 torr.

11. The method of claim 1, wherein the first pressure is from about 10⁻¹ torr to about 10⁻⁷ torr.

12. The method of claim 1, wherein the second pressure is between the first pressure and atmospheric pressure.

13. The method of claim 1, wherein the second pressure is atmospheric pressure.

14. The method of claim 1, wherein the inert gas comprises argon or helium.

15. The method of claim 14, wherein the inert gas is argon.

16. The method of claim 1, wherein the sapphire lamina is heated at the first temperature and under vacuum at the first pressure and subsequently heated at the second temperature and in the gaseous atmosphere at the second pressure.

17. The method of claim 1, wherein the sapphire lamina is heated at the first temperature and under vacuum at the first pressure, cooled to a temperature below the first temperature, and subsequently heated at the second temperature and in the gaseous atmosphere at the second pressure.

18. The method of claim 17, wherein the sapphire lamina is cooled to room temperature.

19. The method of claim 1, wherein the method further comprises the step of heating the sapphire lamina at a third temperature and in a gaseous atmosphere comprising hydrogen at a third pressure, wherein the third temperature is below the second temperature and the third pressure is above the first pressure.

20. The method of claim 19, wherein the hydrogen comprises water.

21. The method of claim 19, wherein the gaseous atmosphere comprises hydrogen and an inert gas.

22. The method of claim 19, wherein the sapphire lamina is heated in the gaseous atmosphere comprising hydrogen prior to the step of heating the sapphire lamina at the second temperature and in the inert gas at the second pressure.

23. The method of claim 19, wherein the sapphire lamina is heated in the gaseous atmosphere comprising hydrogen prior to the step of heating the sapphire lamina at the first temperature and under vacuum at the first pressure.

24. The method of claim 1, wherein the sapphire lamina is provided in an annealing furnace.

25. The method of claim 1, wherein a plurality of sapphire lamina are provided.

26. The method of claim 1, wherein the cover plate is the sapphire lamina.

27. The method of claim 1, wherein the cover plate is two or more layers, and the sapphire lamina is an exterior layer of the cover plate.

28. The method of claim 27, wherein the cover plate further comprises a transparent layer affixed to the sapphire layer.

29. The method of claim 28, wherein the transparent layer has a front surface, and wherein the sapphire layer is affixed to the front surface.

30. The method of claim 29, wherein the subsurface layer comprises glass.

31. The method of claim 29, wherein the subsurface layer comprises a polymeric material.

32. The method of claim 1, wherein the electronic device comprises at least one display element having a display surface and wherein the cover plate is affixed to the display surface.

33. The method of claim 1, wherein the electronic device comprises at least one display element having a display surface and wherein the cover plate is a protective layer removably positioned on top of the display surface.

34. The method of claim 1, wherein the electronic device is an electronic media player, a mobile telephone, a personal data assistant, a pager, a tablet, a laptop computer, or an electronic notebook

35. A cover plate for an electronic device prepared by a method comprising the steps of:
i) providing at least one sapphire lamina;
ii) heating the sapphire lamina at a first temperature and under vacuum at a first pressure;
iii) heating the sapphire lamina at a second temperature and in an inert gaseous atmosphere at a second pressure, wherein the second temperature is greater than the first temperature and the second pressure is greater than the first pressure;
iv) cooling the sapphire lamina to room temperature to produce an annealed sapphire lamina; and
v) fabricating the cover plate comprising the annealed sapphire lamina.

36. An electronic device comprising a cover plate prepared by a method comprising the steps of:
i) providing at least one sapphire lamina;
ii) heating the sapphire lamina at a first temperature and under vacuum at a first pressure;
iii) heating the sapphire lamina at a second temperature and in an inert gaseous atmosphere at a second pressure, wherein the second temperature is greater than the first temperature and the second pressure is greater than the first pressure;
iv) cooling the sapphire lamina to room temperature to produce an annealed sapphire lamina; and
v) fabricating the cover plate comprising the annealed sapphire lamina.
